(19) United States
(12) Patent Application Publication
(10) Pub. No.: US 2020/0203326 A1
(43) Pub. Date: Jun. 25, 2020

(54) PACKAGE ON PACKAGE ASSEMBLY

(71) Applicant: Intel Corporation, Sanra Clara, CA (US)

(72) Inventor: Hyoung Il KIM, Folsom, CA (US)

(21) Appl. No.: 16/637,548

(22) PCT Filed: Sep. 29, 2017
(86) PCT No.: PCT/US2017/054391

§ 371 Date: Feb. 7, 2020

(51) Int. Cl. H01L 25/10; H01L 25/18; H01L 25/00

(52) U.S. Cl. CPC H01L 25/105; H01L 2225/1064; H01L 25/50; H01L 25/18

(57) ABSTRACT

Embodiments herein relate to a package-on-package assembly that may include a first package with the first side coupled to a printed circuit board (PCB) and a second side opposite the first side, a second package coupled with the second side of the first package, where the second package is a leadframe package with one or more leads coupled with the PCB, where the first package and the second package are electrically coupled through the PCB. Other embodiments may be described and/or claimed.

### FIELD

Embodiments of the present disclosure generally relate to the field of package assemblies, and in particular a ball grid array (BGA) package on package (PoP) assemblies.

### BACKGROUND

Continued reduction in the end-product size of mobile electronic devices such as smartphones and Ultrabooks is a driving force for the development of packaging with a small form factor. BGA PoP implementations are increasing in popularity, particularly in the mobile industry, due to a reduced printed circuit board (PCB) size. Legacy PoP implementations, however, require long development cycles, incur high costs, create complex inventory management, and have assembly yield-control issues.

### BRIEF DESCRIPTION OF THE DRAWINGS

FIGS. 1A-1B illustrate an example of a PoP assembly with a J-lead lead type package at various stages of a manufacturing process, in accordance with embodiments.

FIGS. 2A-2B illustrate an example of a PoP assembly with a gull-wing type package at various stages of a manufacturing process, in accordance with embodiments.

FIG. 3 a block diagram that illustrates a process for assembling a PoP, in accordance with various embodiments.

FIG. 4 schematically illustrates a computing device, in accordance with embodiments.

### DETAILED DESCRIPTION

Embodiments of the present disclosure generally relate to apparatuses and techniques for creating a BGA PoP assembly that uses a leadframe package. The leadframe package may have J-leads or gull-wing leads. In embodiments, the leadframe package may be placed on top of a BGA package that may be coupled with a PCB. In embodiments, the top and bottom packages may communicate through the PCB using the leads of the leadframe package instead of using a through mold via (TMV).

In embodiments, implementations may result in cost reductions over legacy BGA PoP assemblies. For example, certain assembly costs may be avoided, such as TMV process costs, PoP interconnection costs, costs of advanced substrates, and additional assembly processes. In addition, there may be inventory advantages because the first and second packages of the PoP assembly may be individually functional and therefore may be independently sold. In addition, there may be a shorter development cycle over legacy implementations and higher assembly yields because no complex interconnections between the top and bottom package is required.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an ASIC, an electronic circuit, a processor (shared, dedicated, or group) and/or memory (shared, dedicated, or group) that execute one or more software or firmware programs, a combinational logic circuit, and/or other suitable components that provide the described functionality.

Various figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the figures, and sizes, thicknesses, or dimensions may be assumed for some embodiments only where specifically indicated or discussed.

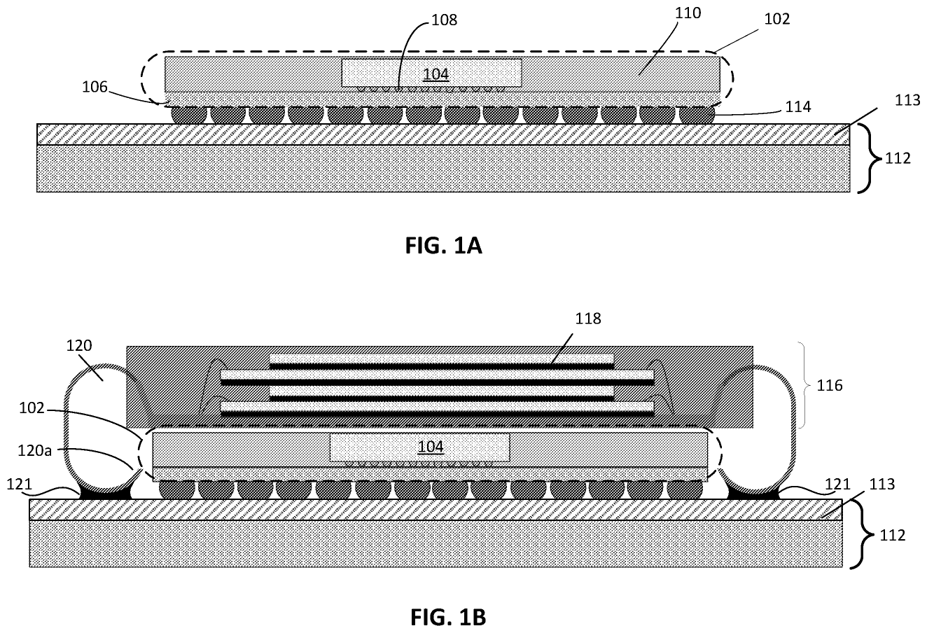

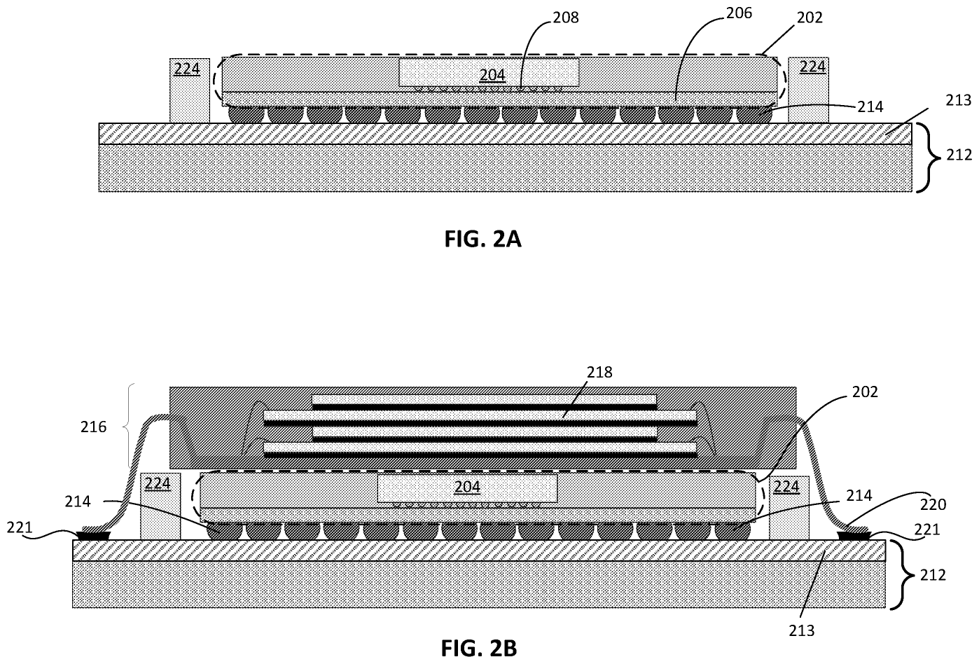

FIGS. 1A-1B and 2A-2B depict examples of such a package assembly at various stages of the manufacturing process. In embodiments, one or more elements may be introduced in an earlier figure, for example, FIG. 1A, and then may be assumed to carry over to later figures such as FIG. 1B. Therefore, each and every element of the package assemblies shown may not be labeled in each and every stage of each figure for the sake of clarity and the ease of understanding.

In embodiments, PoP processes may be used to combine vertically discrete logic and memory BGA packages. Two or more of these packages may be installed, or “stacked,” on top of each other. This PoP configuration may allow higher component densities within devices, such as mobile phones, personal digital assistants (PDA), baseband modems, and the like. Prior to PoP assembly, each of the packages within the PoP may be individually tested to achieve a higher PoP assembly yield.

Example of PoP configurations may include pure memory stacking or mixed logic-memory stacking. In pure memory stacking, two or more memory-only packages may be stacked on each other. In mixed logic-memory stacking, a logic package that may contain a central processing unit (CPU) or other integrated circuit (IC) may be on the bottom of the PoP assembly and a memory package may be on the top of the PoP assembly. For example, the bottom package may be a system on-chip (SoC) for a mobile device and the memory for the SoC may be in the top package. Frequently, the logic package is on the bottom, for example adjacent to a motherboard, due to the number of connections that may be required between the logic package and the motherboard.

In legacy implementations, solder is used to electrically couple a top package, for example the package in the PoP assembly that is furthest away from the motherboard, to the bottom package through the motherboard. In legacy implementations, the solder connection may be formed by embedding the bottom package in a molding after it is attached to a substrate. Then, a through-mold via (TMV) is drilled in the molding, and the TMV is filled with solder before attaching the top package.

Turning back to the disclosure herein, embodiments may include the top package as a leadframe package that includes metal structures, referred to as “leads” or “pins,” shaped as J-leads or gull-wing leads to carry signals from one or more dies within the top package to outside the package. When the PoP assembly is created, these leads may electrically connect with a PCB to which the bottom package is electrically coupled, creating an electrical routing between the top package and the bottom package through the PCB. The leads of the leadframe (top) package may be manufactured by removing material from a flat plate of copper or copper-alloy by stamping or by etching.

FIGS. 1A-1B illustrate an example of a PoP assembly with a J-lead type package at various stages of a manufacturing process, in accordance with embodiments.

FIG. 1A shows a first package 102 that may include an integrated circuit (IC) 104. The IC 104 may include one or more CPUs, SoCs, application specific integrated circuits (ASICs), memory chips, such as dynamic random access memory (DRAM) chips, or may include some other IC.

The IC 104 may be electrically coupled with a substrate 106 using micro-bumps 108. In embodiments, micro-bumps 108 may be solder micro-bumps. The substrate 106 may include a redistribution layer (RDL) or other electrical routing features to route electrical signals from the IC 104 through micro-bumps 108 to outside the package 102. The IC 104 may encased within a fill material 110, which may include a resin or an epoxy. The fill material 110 may also underfill the micro-bumps 108.

The first package 102 may be coupled with a PCB 112 using a BGA 114. In embodiments, the PCB 112 may be a motherboard, or may be substrate with an RDL 113 or with other electrical routing features to route electrical signals to and from the first package 102 using the BGA 114.

FIG. 1B shows a second package 116 that may be physically coupled with the first package 102. The second package 116 may be referred to as a top package and the first package 102 may be referred to as a bottom package. In embodiments, there may be no electrical coupling between the second package 116 and the first package 102 where the second package 116 and the first package 102 are physically coupled.

The second package 116 may include one or more DRAM chips 118. In embodiments, the second package 116 may include one or more other ICs such as CPUs, SoCs, ASICs or other ICs. The second package 116 may be a leadframe package having multiple leads to connect the DRAM chips 118 to outside the second package 116. In embodiments, the multiple leads may include a J-lead 120.

In embodiments, a J-lead 120 may be a lead that is bent, folded, or otherwise formed into a “J” to form a J-lead end 120a to curl under the second package 116 body. A plurality of J-leads 120 may allow an electrical connection to be made between the second package 116 and the PCB 112 while keeping the footprint area size of the second package 116 with the J-leads 120 similar to the footprint area size of the second package 116 without the J-leads 120.

After the second package 116 is physically coupled with the first package 102 one or more J-leads 120 may be electrically coupled with electrical routings or RDL 113 part of the PCB 112. In embodiments, the J-leads 120 may be coupled with the PCB 112 using solder 121. In embodiments, the length or shape of the one or more J-leads 120 may be customized to allow the physical coupling of the first package 102 and the second package 116 and the electrical coupling of the J-leads 120 to the PCB 112.

The completed PoP assembly will electrically couple the IC 104 and the DRAM 118 through the micro-bumps 108, the substrate 106, the BGA 114, the PCB 112 and the J-lead 120. In addition, in embodiments the footprint area size of the PoP assembly may be substantially similar to the footprint area size of the second package 116. In embodiments, the second package 116 may be physically connected with the PCB 112 but not electrically coupled with the RDL 113.

FIGS. 2A-2B illustrate an example of a PoP assembly with a gull-wing type package at various stages of a manufacturing process, in accordance with embodiments.

FIG. 2A shows a first package 202, which may be similar to first package 102 of FIG. 1A, that may include an IC 204, which may be similar to IC 104, coupled with a substrate 206, which may be similar to substrate 206, via micro-bumps 208, which may be similar to micro-bumps 108. In embodiments, the first package 202 may be coupled with the PCB 212, which may be similar to PCB 112, using BGA 214, which may be similar to BGA 114.

In embodiments, other devices 224, may be coupled with the PCB 212 and may be placed near or adjacent to the first package 202. The other devices 224 may include passive devices such as resistors, capacitors, inductors, transformers, diodes, and the like. In embodiments, the z-heights of the other devices 224 from a surface of the PCB 212 may be less than or equal to a z-height of the first package 202 from the surface of the PCB 212.

FIG. 2B shows a second package 216, that may be similar to second package 116 of FIG. 1B, physically coupled with the first package 202. The second package 216 may be referred to as a top package. In embodiments, there may be no electrical coupling between the second package 216 and the first package 202 where the second package 216 and the first package 202 are physically coupled.

In embodiments, the second package 216 may include one or more DRAM chips 218, which may be similar to the DRAM chips 118. In embodiments, the second package 216 may be a lead frame package having multiple leads connecting the DRAM chips 218 to outside the second package 216. In embodiments, the multiple leads may include a gull-wing lead 220.

In embodiments, a gull-wing lead 220 may be a lead that is extended out from the second package 216 in the shape of a gull wing and may couple with the PCB 212 at a location further away from the second package 216 in comparison to the J-lead 120 of FIG. 1B. In embodiments, after the PoP assembly is complete, the gull-wing lead 220 may pass over the other devices 224 and electrically couple with the PCB 212 via the RDL 213. In embodiments, the gull-wing lead 220 may be coupled with the PCB 212 using solder 221. In embodiments, the length or shape of the one or more gull-wing leads 220 may be customized to allow the physical coupling of the first package 202 and the second package 216 and the electrical coupling of the gull-wing leads 220 to the PCB 212 via RDL 213 so that operation of the other devices 224 is not adversely affected. In embodiments, the second package 216 may be physically connected with the PCB 212 but not electrically coupled with the RDL 213.

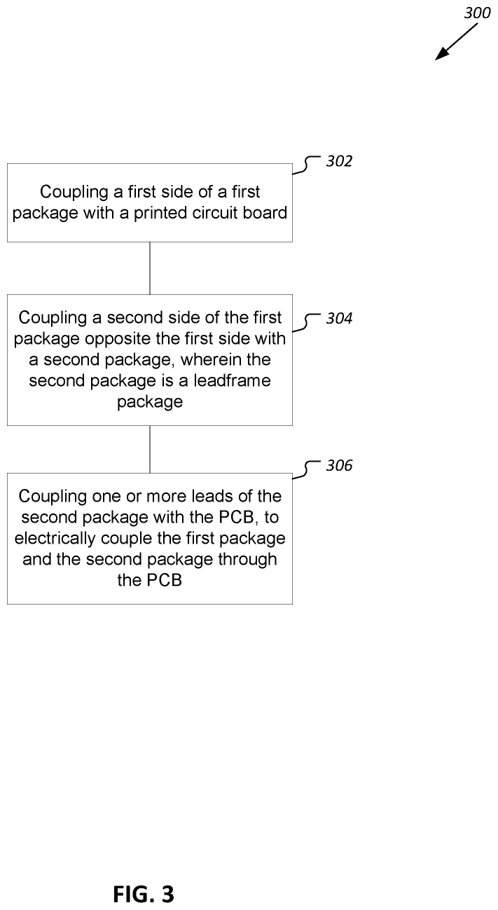

FIG. 3 a block diagram that illustrates a process for assembling a PoP, in accordance with various embodiments. Process 300 may be used for manufacturing a package assembly such as the package assemblies of FIG. 1B or FIG. 2B, according to various embodiments.

At block 302, the process may include coupling a first side of a first package with a PCB. In embodiments, the first package may be the first package 102 of FIG. 1A or the first package 202 of FIG. 2A. The printed circuit board may correspond to PCB 112 or PCB 212 and may include an RDL 113, 213 or other electrical routing features. The coupling may include coupling using a BGA such as BGA 114, 214. In embodiments, the coupling may be performed using a flip-chip process or other suitable process.

In embodiments, other devices such as other devices 224, which may include passive devices, may be coupled with the PCB 212 and may be placed near or adjacent to the first package 202. In these embodiments, the z-heights of the other devices 224 from a surface of the PCB 212 may be less than or equal to a z-height of the first package 202 from the surface of the PCB 212.

At block 304, the process may include coupling a second side of the first package opposite the first side with a second package, wherein the second package is a leadframe package.

In embodiments, the first package 102, 202 and the second package 116, 216 may be physically coupled using any suitable process. After physical coupling, the first package 102, 202 and the second package 116, 216 may be stacked. In embodiments, there may be no electrical coupling where the first package 102, 202 is physically coupled with the second package 116, 216. For example, there may be no TMV nor any other electrical connection between the first package 102, 202 and the second package 116, 216 at any point where the first package 102, 202 and the second package 116, 216 are physically coupled.

In embodiments, the second package 116, 216 may be a leadframe package, for example a quad flat package (QFP), thin small outline package (TSOP), or other suitable leadframe package. In embodiments, the second package 116, 216 may have a J-lead 120, a gull-wing lead 220, or some other suitable lead that will cause the second package 116, 216 to be electrically coupled outside the second package.

At block 306, the process may include coupling one or more leads of the second package with the PCB, to electrically couple the first package and the second package through the PCB.

In embodiments where the second package 116 is a leadframe package with a plurality of J-leads 120, the leads may be soldered or otherwise attached to an RDL or other routing feature of the PCB 112. These embodiments may provide a compact overall PoP implementation that may allow the PCB 112 to have substantially the same footprint area size as the footprint area size of the second package 102 of FIG. 1B.

In embodiments where the second package 216 is a leadframe package with a plurality of gull-wing leads 220, the leads may be may be soldered or otherwise attached to an RDL or other routing feature of the PCB 212. These embodiments may allow the gull-wing lead 220 to go over or otherwise avoid contact with additional devices, such as passive devices 224 adjacent or in close proximity to the first package 202, that are coupled with the PCB 212. As a result, the gull-wing leads 220 may not adversely affect the operation of the passive devices 224.

After assembly, the IC 104, 204 and the DRAM 118 may be electrically coupled by the micro-bumps 104, 204, the substrate 106, 206, the BGA 114, 214, the PCB 112, 220, and the J-type lead 120 or gull-type lead 220.

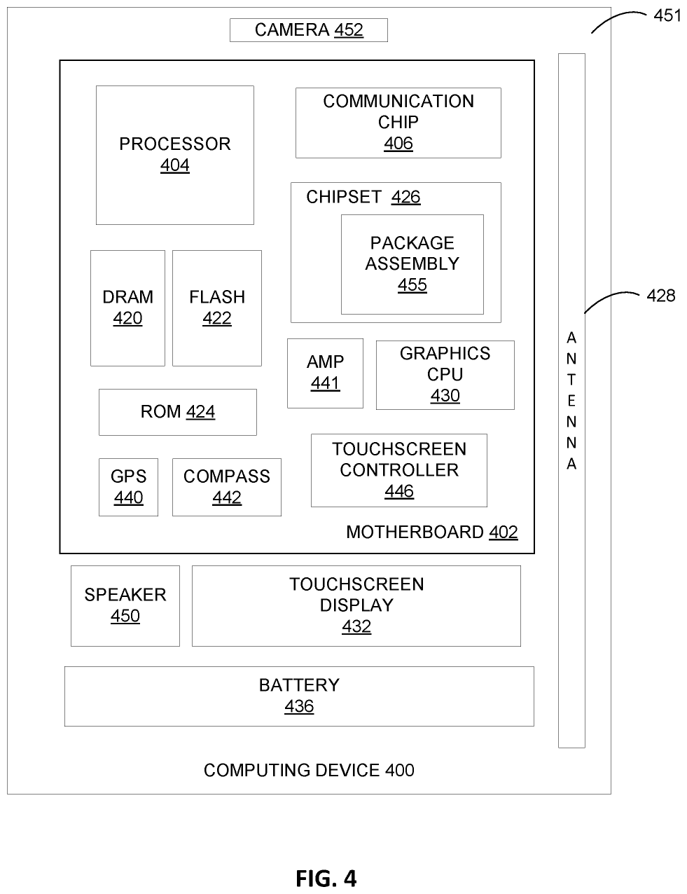

Embodiments of the present disclosure may be implemented into a system using any suitable hardware and/or software to configure as desired. FIG. 4 schematically illustrates a computing device 400 in accordance with one embodiment. The computing device 400 may house a board such as motherboard 402 (i.e., housing 451). The motherboard 402 may include a number of components, including but not limited to a processor 404 and at least one communication chip 406. The processor 404 may be physically and electrically coupled to the motherboard 402. In some implementations, the at least one communication chip 406 may also be physically and electrically coupled to the motherboard 402. In further implementations, the communication chip 406 may be part of the processor 404.

Depending on its applications, computing device 400 may include other components that may or may not be physically and electrically coupled to the motherboard 402. These other components may include, but are not limited to, volatile memory (e.g., DRAM) 420, non-volatile memory (e.g., ROM) 424, flash memory 422, a graphics processor 430, a digital signal processor (not shown), a crypto processor (not shown), a chipset 426, an antenna 428, a display (not shown), a touchscreen display 432, a touchscreen controller 446, a battery 436, an audio codec (not shown), a video codec (not shown), a power amplifier 441, a global positioning system (GPS) device 440, a compass 442, an accelerometer (not shown), a gyroscope (not shown), a speaker 450, a camera 452, and a mass storage device (such as hard disk drive, compact disk (CD), digital versatile disk (DVD), and so forth) (not shown). Further components, not shown in FIG. 4, may include a microphone, a filter, an oscillator, a pressure sensor, or an RFID chip. In embodiments, one or more of the package assembly components 455 may be a package assembly such as the package assemblies of FIG. 1B or 2B.

The communication chip 406 may enable wireless communications for the transfer of data to and from the computing device 400. The term “wireless” and its derivatives may be used to describe circuits, devices, systems, processes, techniques, communications channels, etc., that may communicate data through the use of modulated electromagnetic radiation through a non-solid medium. The term does not imply that the associated devices do not contain any wires, although in some embodiments they might not. The communication chip 406 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible broadband wireless access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 406 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 406 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 406 may operate in accordance with Code Division Multiple Access (CDMA), Time Division Multiple Access (TDMA), Digital Enhanced Cordless Telecommunications (DECT), Evolution-Data Optimized (EV-DO), derivatives thereof, as well as any other wireless protocols that are designated as 3G, 4G, 5G, and beyond. The communication chip 406 may operate in accordance with other wireless protocols in other embodiments.

The computing device 400 may include a plurality of communication chips 406. For instance, a first communication chip 406 may be dedicated to shorter range wireless communications such as Wi-Fi and Bluetooth and a second communication chip 406 may be dedicated to longer range wireless communications such as GPS, EDGE, GPRS, CDMA, WiMAX, LTE, EV-DO, and others.

The processor 404 of the computing device 400 may include a die in a package assembly such as, for example, one of the package assemblies of FIG. 1B or 2B described herein. The term “processor” may refer to any device or portion of a device that processes electronic data from registers and/or memory to transform that electronic data into other electronic data that may be stored in registers and/or memory.

In various implementations, the computing device 400 may be a laptop, a netbook, a notebook, an Ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 400 may be any other electronic device that processes data, for example, an all-in-one device such as an all-in-one fax or printing device.

### EXAMPLES

Example 1 may be a package-on-package (PoP) assembly comprising: a first package with a first side coupled with a printed circuit board (PCB) and a second side opposite the first side; a second package coupled with a second side of the first package; and wherein the second package is a leadframe package with one or more leads coupled with the PCB.

Example 2 may include the assembly of example 1, wherein the first package and the second package are electrically coupled through the PCB by the one or more leads.

Example 3 may include the assembly of example 1, wherein the second package and the second side of the first package are electrically isolated.

Example 4 may include the assembly of example 1, wherein the first package is coupled with the PCB by a ball grid array (BGA).

Example 5 may include the assembly of any one of examples 1-4, wherein the one or more leads is a J-lead or a gull-wing lead.

Example 6 may include the assembly of example 5, wherein the one or more leads is a gull-wing lead; and further comprising one or more passive components coupled with the PCB, wherein the one or more passive components are at least partially disposed between one of the gull-wing leads and the PCB.

Example 7 may include the assembly of any one of examples 1-4, wherein the first package is coupled with the PCB with reflow or with a surface mount.

Example 8 may include the assembly of any one of examples 1-4, wherein the second package is coupled with the first package or the PCB with reflow.

Example 9 may include the assembly of any one of examples 1-4, wherein the first package includes a first integrated circuit and the second package includes a second integrated circuit.

Example 10 may include the assembly of example 9, wherein the first integrated circuit is a central processing unit (CPU) and the second integrated circuit is dynamic random access memory (DRAM).

Example 11 may include the assembly of any one of examples 1-4, wherein the first package is a BGA package.

Example 12 may include the assembly of any one of examples 1-4, wherein the second package is a quad flat package (QFP) or a thin small outline package (TSOP).

Example 13 may be a method for creating a package-on-package (PoP) assembly, comprising: coupling a first side of a first package with a printed circuit board (PCB); and coupling a second side of the first package opposite the first side with a second package, wherein the second package is a leadframe package.

Example 14 may include the method of example 13, further comprising coupling one or more leads of the second package with the PCB, to electrically couple the first package and the second package through the PCB.

Example 15 may include the method of example 13, wherein the second package and the second side of the first package are electrically isolated.

Example 16 may include the method of example 13, wherein coupling the first side of the first package with the PCB includes coupling the first side of the first package with the PCB using a ball grid array (BGA).

Example 17 may include the method of any one of examples 13-16, wherein the one or more leads is a J-lead or a gull-wing lead.

Example 18 may include the method of example 17, wherein the one or more leads is a gull-wing lead; and further comprising coupling one or more passive components with the PCB, wherein the one or more passive components are at least partially disposed between one of the gull-wing leads and the PCB.

Example 19 may include the method of any one of examples 13-16, wherein coupling the first side of the first package with the PCB further includes coupling the first package with the PCB using reflow or a surface mount.

Example 20 may include the method of any one of examples 13-16, wherein coupling the second side of the first package with the second package further includes coupling the second side of the first package with the second package using reflow.

Example 21 may include the method of any one of examples 13-16, wherein the first package includes a first integrated circuit and the second package includes a second integrated circuit.

Example 22 may include the method of example 21, wherein the first integrated circuit is a central processing unit (CPU) or the second integrated circuit is a dynamic random access memory (DRAM).

Example 23 may include the method of any one of examples 13-16, wherein the first package is a BGA package.

Example 24 may include the method of any one of examples 13-16, wherein the second package is a quad flat package (QFP) or a thin small outline package (TSOP).

Example 25 may be a system with a package-on-package assembly, the system comprising: a circuit board; a package-on-package assembly coupled with the circuit board, the assembly comprising: a first package with a first side coupled with a printed circuit board (PCB); a second package coupled with a second side of the first package opposite the first side; and wherein the second package is a leadframe package with one or more leads coupled with the PCB.

Example 26 may include the system of example 25, wherein the first package and the second package are electrically coupled through the PCB by the one or more leads.

Example 27 may include the system of example 25, wherein the second package and the second side of the first package are electrically isolated.

Example 28 may include the system of example 25, wherein the first package is coupled with the PCB by a ball grid array (BGA).

Example 29 may include the system of any one of examples 25-28, wherein the one or more leads is a J-lead or a gull-wing lead.

Example 30 may include the system of example 29, wherein the one or more leads is a gull-wing lead; and further comprising one or more passive components coupled with the PCB, wherein the one or more passive components are at least partially disposed between one of the gull-wing leads and the PCB.

Example 31 may include the system of any one of examples 25-28, wherein the first package is coupled with the PCB with reflow or with a surface mount.

Example 32 may include the system of any one of examples 25-28, wherein the second package is coupled with the first package or the PCB with reflow.

Example 33 may include the system of any one of examples 25-28, wherein the first package includes a first integrated circuit and the second package includes a second integrated circuit.

Example 34 may include the system of example 33, wherein the first integrated circuit is a central processing unit (CPU) and the second integrated circuit is dynamic random access memory (DRAM).

Example 35 may include the system of any one of examples 25-28, wherein the first package is a BGA package.

Example 36 may include the system of any one of examples 25-28, wherein the second package is a quad flat package (QFP) or a thin small outline package (TSOP).

Example 37 may be a device comprising: means for coupling a first side of a first package with a printed circuit board (PCB); and means for coupling a second side of the first package opposite the first side with a second package, wherein the second package is a leadframe package.

Example 38 may include the device of example 37, further comprising means for coupling one or more leads of the second package with the PCB, to electrically couple the first package and the second package through the PCB.

Example 39 may include the device of example 37, wherein the second package and the second side of the first package are electrically isolated.

Example 40 may include the device of example 37, wherein means for coupling the first side of the first package with the PCB includes means for coupling the first side of the first package with the PCB using a ball grid array (BGA).

Example 41 may include the device of any one of examples 37-40, wherein the one or more leads is a J-lead or a gull-wing lead.

Example 42 may include the device of example 41, wherein the one or more leads is a gull-wing lead; and further comprising means for coupling one or more passive components with the PCB, wherein the one or more passive components are at least partially disposed between one of the gull-wing leads and the PCB.

Example 43 may include the device of any one of examples 37-40, wherein means for coupling the first side of the first package with the PCB further includes means for coupling the first package with the PCB using reflow or a surface mount.

Example 44 may include the device of any one of examples 37-40, wherein means for coupling the second side of the first package with the second package further includes means for coupling the second side of the first package with the second package using reflow.

Example 45 may include the device of any one of examples 37-40, wherein the first package includes a first integrated circuit and the second package includes a second integrated circuit.

Example 46 may include the device of example 45, wherein the first integrated circuit is a central processing unit (CPU) or the second integrated circuit is a dynamic random access memory (DRAM).

Example 47 may include the device of any one of examples 37-40, wherein the first package is a BGA package.

Example 48 may include the device of any one of examples 37-40, wherein the second package is a quad flat package (QFP) or a thin small outline package (TSOP).

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or to limit embodiments to the precise forms disclosed. While specific embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims. Rather, the scope of the invention is to be determined entirely by the following claims, which are to be construed in accordance with established doctrines of claim interpretation.

1-25. (canceled)

26. A package-on-package (PoP) assembly comprising:
a first package with a first side coupled with a printed circuit board (PCB) and a second side opposite the first side;
a second package coupled with a second side of the first package;
wherein the second package is a leadframe package with one or more leads coupled with the PCB; and
wherein the first package and the second package are electrically coupled through the PCB by the one or more leads.

27. The assembly of claim 26, wherein the second package and the second side of the first package are electrically isolated.

28. The assembly of claim 26, wherein the first package is coupled with the PCB by a ball grid array (BGA).

29. The assembly of claim 26, wherein the one or more leads is a J-lead or a gull-wing lead.

30. The assembly of claim 29, wherein the one or more leads is a gull-wing lead; and
further comprising one or more passive components coupled with the PCB, wherein the one or more passive components are at least partially disposed between one of the gull-wing leads and the PCB.

31. The assembly of claim 26, wherein the first package is coupled with the PCB with reflow or with a surface mount.

32. The assembly of claim 26, wherein the second package is coupled with the first package or the PCB with reflow.

33. The assembly of claim 26, wherein the first package includes a first integrated circuit and the second package includes a second integrated circuit.

34. The assembly of claim 33, wherein the first integrated circuit is a central processing unit (CPU) and the second integrated circuit is dynamic random access memory (DRAM).

35. The assembly of claim 26, wherein the first package is a BGA package.

36. The assembly of claim 26, wherein the second package is a quad flat package (QFP) or a thin small outline package (TSOP).

37. A method for creating a package-on-package (PoP) assembly, comprising:
coupling a first side of a first package with a printed circuit board (PCB);
coupling a second side of the first package opposite the first side with a second package, wherein the second package is a leadframe package; and
coupling one or more leads of the second package with the PCB, to electrically couple the first package and the second package through the PCB.

38. The method of claim 37, wherein the second package and the second side of the first package are electrically isolated.

39. The method of claim 37, wherein coupling the first side of the first package with the PCB includes coupling the first side of the first package with the PCB using a ball grid array (BGA).

40. The method of claim 36, wherein the one or more leads is a J-lead or a gull-wing lead.

41. The method of claim 40, wherein the one or more leads is a gull-wing lead; and further comprising coupling one or more passive components with the PCB, wherein the one or more passive components are at least partially disposed between one of the gull-wing leads and the PCB.

42. A system with a package-on-package assembly, the system comprising:
a circuit board;
a package-on-package assembly coupled with the circuit board, the assembly comprising:
a first package with a first side coupled with a printed circuit board (PCB);
a second package coupled with a second side of the first package opposite the first side;
wherein the second package is a leadframe package with one or more leads coupled with the PCB; and
wherein the first package and the second package are electrically coupled through the PCB by the one or more leads.

43. The system of claim 42, wherein the second package and the second side of the first package are electrically isolated.

44. The system of claim 42, wherein the first package is coupled with the PCB by a ball grid array (BGA).

45. The system of claim 42, wherein the one or more leads is a J-lead or a gull-wing lead.

46. The system of claim 42, wherein the one or more leads is a gull-wing lead; and
further comprising one or more passive components coupled with the PCB, wherein the one or more passive components are at least partially disposed between one of the gull-wing leads and the PCB.

47. A device comprising:
means for coupling a first side of a first package with a printed circuit board (PCB);
means for coupling a second side of the first package opposite the first side with a second package, wherein the second package is a leadframe package; and
means for coupling one or more leads of the second package with the PCB, to electrically couple the first package and the second package through the PCB.

48. The device of claim 47, wherein the second package and the second side of the first package are electrically isolated.

49. The device of claim 47, wherein means for coupling the first side of the first package with the PCB includes means for coupling the first side of the first package with the PCB using a ball grid array (BGA).

50. The device of claim 47, wherein the one or more leads is a J-lead or a gull-wing lead.
